(19) United States
(12) Patent Application Publication
(10) Pub. No.: US 2026/0274737 A1
(43) Pub. Date: Sep. 17, 2026

(54) WINDOW, DISPLAY DEVICE INCLUDING THE WINDOW, AND ELECTRONIC DEVICE INCLUDING THE WINDOW

(71) Applicant: Samsung Display Co., LTD., Yongin-si (KR)

(72) Inventors: HOIKWAN LEE, Yongin-si (KR); Jun Yeub LEE, Yongin-si (KR); SUNGWON KIM, Yongin-si (KR); SANGDUK LEE, Yongin-si (KR)

(21) Appl. No.: 19/421,317

(22) Filed: Dec. 16, 2025

(30) Foreign Application Priority Data
Mar. 12, 2025 (KR) 10-2025-0032347

(51) Int. Cl. C03C 3/064; C03C 3/089; C03C 3/091; H05K 5/03

(52) U.S. Cl. CPC C03C 3/064; C03C 3/089; C03C 3/091; H05K 5/03

(57) ABSTRACT

A window includes a glass substrate having a thickness of about 50 μm to about 100 μm. The glass substrate includes about 5 mol % to about 45 mol % of SiO₂, about 5 mol % to about 30 mol % of R₂O, and about 45 mol % to about 90 mol % of A₂O₃, based on an entirety of the glass substrate, where R is at least one selected from K, Na, and Li, and A is at least one selected from B and Al. In a temperature range of about −40° C. to about 200° C., a Young's modulus of the glass substrate is about 30 GPa to about 50 GPa.

This application claims priority to Korean Patent Application No. 10-2025-0032347, filed on Mar. 12, 2025, and all the benefits accruing therefrom under 35 U.S.C. § 119, the content of which in its entirety is herein incorporated by reference.

### BACKGROUND

The present disclosure herein relates to a window, and a display device and an electronic device each including the window, and more particularly, to a window including a glass substrate with excellent impact resistance, and flexible display device and electronic device each including the window.

Display devices are used for various multimedia devices such as televisions, mobile phones, tablet computers, and game consoles, in order to provide image information for users. Recently, flexible display devices having various shapes capable of folding or bending are being developed.

The flexible display devices may include display modules and windows each capable of folding or bending. The windows included in the display devices effectively deliver image information received from the display modules to the outside, and protect the display modules from the outside.

Glass substrates used for the windows of the flexible display devices may be ultra-thin glass substrates. The ultra-thin glass substrates are required to be foldable or bendable and also have excellent impact resistance against external impacts or impacts caused by users' inputs. Accordingly, developments are conducted for compositions of the ultra-thin glass substrates having the excellent impact resistance.

### SUMMARY

The present disclosure provides a window including a glass substrate having excellent impact resistance and surface quality characteristics.

The present disclosure also provides a display device and an electronic device each having excellent impact resistance and surface quality characteristics and capable of folding.

An embodiment of the invention provides a window including a glass substrate having a thickness of about 50 micrometers (m) to about 100 μm. The glass substrate includes about 5 mole percents (mol %) to about 45 mol % of SiO₂, about 5 mol % to about 30 mol % of R₂O, and about 45 mol % to about 90 mol % of A₂O₃, based on an entirety of the glass substrate, where R is at least one selected from potassium (K), Na, and Li, and A is at least one selected from boron (B) and Al. In a temperature range of about −40° C. to about 200° C., a Young's modulus of the glass substrate is about 30 gigapascals (GPa) to about 50 GPa.

In an embodiment, the glass substrate may not include CaO, MgO, BaO, PbO, and ZnO.

In an embodiment, the glass substrate may be composed of SiO₂, R₂O, and A₂O₃.

In an embodiment, the glass substrate may further include XO, and X may be at least one selected from Ca, Mg, Ba, Pb, and Zn. The glass substrate may include greater than 0 mol % and equal to or less than 1 mol % of XO based on the entirety of the glass substrate.

In an embodiment, the glass substrate may include Na₂O or K₂O but not include Li₂O.

In an embodiment, a glass transition temperature of the glass substrate may be about 350° C. to about 700° C.

In an embodiment, a density of the glass substrate may be about 1.9 grams per cubic centimeters (g/cm³) to about 2.3 g/cm³.

In an embodiment, a surface quality index of the glass substrate may be about 0.01 Kc to about 0.1 Kc.

In an embodiment, the glass substrate may include about 45 mol % to about 90 mol % of B₂O₃.

In an embodiment, the glass substrate may include about 55 mol % to about 70 mol % of B₂O₃ and include greater than 0 mol % and equal to or less than 20 mol % of Al₂O₃.

In an embodiment of the invention, a display device includes a display module, and a window disposed on the display module and including a glass substrate having a thickness of about 50 μm to about 100 μm. The glass substrate includes about 5 mol % to about 45 mol % of SiO₂, about 5 mol % to about 30 mol % of R₂O, and about 45 mol % to about 90 mol % of A₂O₃, based on an entirety of the glass substrate. R is at least one selected from K, Na, and Li, and A is at least one selected from B and Al.

In an embodiment, in a temperature range of about −40° C. to about 200° C., a Young's modulus of the glass substrate may be about 30 GPa to about 50 GPa.

In an embodiment, a glass transition temperature of the glass substrate may be about 350° C. to about 700° C.

In an embodiment, a density of the glass substrate may be about 1.9 g/cm³ to about 2.3 g/cm³.

In an embodiment, a surface quality index of the glass substrate may be about 0.01 Kc to about 0.1 Kc.

In an embodiment of the invention, an electronic device includes a display module, and a window disposed on the display module and including a glass substrate having a thickness of about 50 μm to about 100 μm. The glass substrate includes about 5 mol % to about 45 mol % of SiO₂, about 5 mol % to about 30 mol % of R₂O, and about 45 mol % to about 90 mol % of A₂O₃, based on an entirety of the glass substrate, where R is at least one selected from K, Na, and Li, and A is at least one selected from B and Al. In a temperature range of about −40° C. to about 200° C., a Young's modulus of the glass substrate is about 30 GPa to about 50 GPa.

In an embodiment, the electronic device may further include an adhesive layer disposed between the display module and the window.

In an embodiment, the electronic device may include a folding area, and a first non-folding area and a second non-folding area disposed with the folding area therebetween. The folding area may be folded around a folding axis.

In an embodiment, the glass substrate may not include CaO, MgO, BaO, PbO, and ZnO.

In an embodiment, a surface quality index of the glass substrate may be about 0.01 Kc to about 0.1 Kc.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1A is an assembled perspective view illustrating an unfolded state of an electronic device according to an embodiment of the invention;

FIG. 1B is an assembled perspective view illustrating an in-folded state of an electronic device according to an embodiment of the invention;

FIG. 1C is an assembled perspective view illustrating an out-folded state of an electronic device according to an embodiment of the invention;

FIG. 2A is an assembled perspective view illustrating an unfolded state of an electronic device according to an embodiment of the invention;

FIG. 2B is an assembled perspective view illustrating an in-folded state of an electronic device according to an embodiment of the invention;

FIG. 3 is an exploded perspective view of an electronic device according to an embodiment of the invention;

FIGS. 4A and 4B are each a cross-sectional view of a window according to an embodiment of the invention;

FIG. 5 is a graph illustrating stress intensity through thickness for glass substrates having different Young's moduli; and

FIG. 6 is a cross-sectional view of a display module according to an embodiment of the invention.

### DETAILED DESCRIPTION

The invention may be modified in various forms, and particular embodiments thereof will be illustrated in the drawings and described herein in detail. The invention should not be construed as limited to the embodiments set forth herein. Rather, these embodiments are provided so that this disclosure will be thorough and complete, and will fully convey the scope of the invention to those skilled in the art.

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the invention. Similarly, a second element could be termed a first element. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

As used herein, “being directly disposed” may mean that there is no additional layer, film, region, plate or the like between a part such as a layer, film, region, plate or the like and another part. For example, “being directly disposed” may mean that two layers or two members are disposed with no additional member such as an adhesive member between the two layers or two members.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

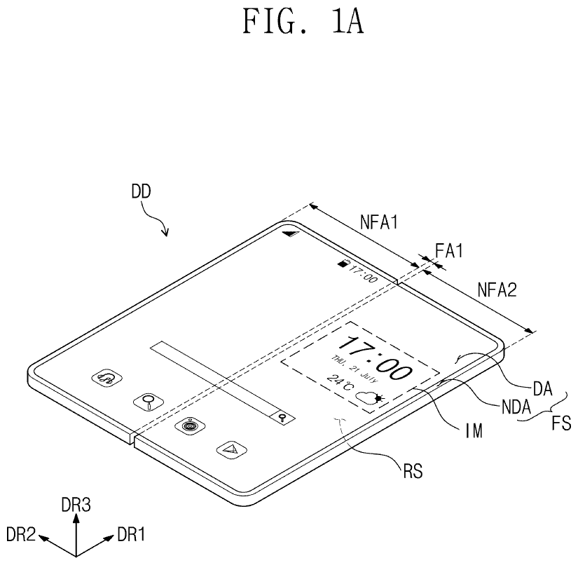

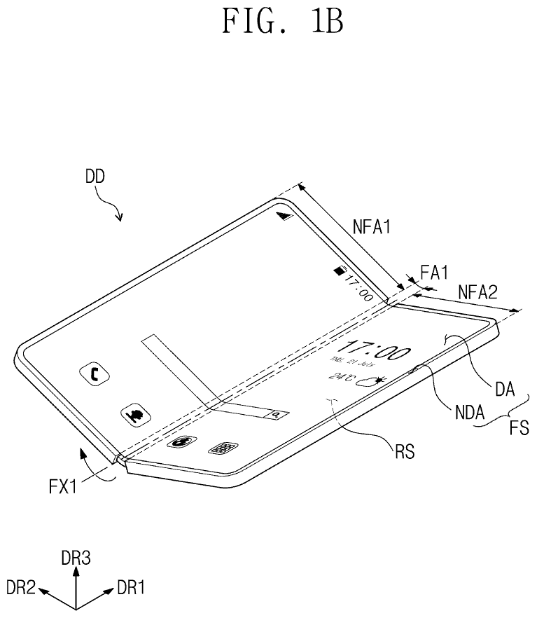

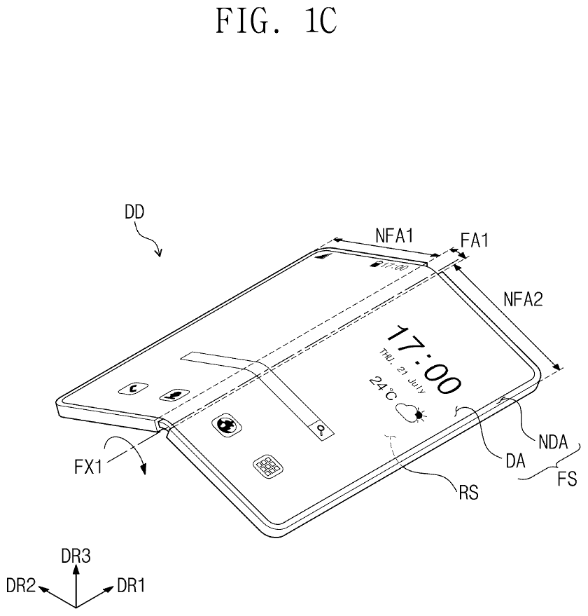

FIG. 1A is an assembled perspective view illustrating an unfolded state of an electronic device DD according to an embodiment of the invention. FIG. 1B is an assembled perspective view illustrating an in-folded state of the electronic device DD according to an embodiment of the invention. FIG. 1C is an assembled perspective view illustrating an out-folded state of the electronic device DD according to an embodiment of the invention.

The electronic device DD according to an embodiment may be a device that is activated in response to an electrical signal. For example, the electronic device DD may be a mobile phone, a tablet computer, a vehicle navigation device, a game console, or a wearable device, but an embodiment is not limited thereto. FIG. 1A and the like used herein illustrate a mobile phone as an example of the electronic device DD. The electronic device DD may be a flexible display device.

FIG. 1A and subsequent figures illustrate a first direction DR1, a second direction DR2, and a third direction DR3, and directions indicated by the first to third directions DR1, DR2 and DR3 used herein are relative concepts and may be changed to other directions.

Referring to FIGS. 1A to 1C, the electronic device DD according to an embodiment may include a first display surface FS defined by a first direction DR1 and a second direction DR2 crossing the first direction DR1. The electronic device DD may provide an image IM for a user through the first display surface FS. The electronic device DD according to an embodiment may display the image IM in the third direction DR3 on the first display surface FS parallel to each of the first direction DR1 and the second direction DR2. As used herein, a front surface (or top surface) and a rear surface (or bottom surface) of each component are defined on the basis of a direction in which the image IM is displayed. The front surface and the rear surface may oppose each other in the third direction DR3, and a normal direction to each of the front surface and the rear surface may be parallel to the third direction DR3.

The electronic device DD according to an embodiment may include the first display surface FS and a second display surface RS. The first display surface FS may include a display area DA and a non-display area NDA. The display area DA may include an electronic module area (not illustrated). The second display surface RS may be defined as a surface opposing at least a portion of the first display surface FS. That is, the second display surface RS may be defined as a portion of a rear surface of the electronic device DD.

The electronic device DD according to an embodiment may detect an external input applied from the outside. The external input may include various types of inputs provided from the outside of the electronic device DD. For example, the external input may include not only a touch by part of the body, such as a user's hand, but also an external input (e.g., hovering) applied by approaching the electronic device DD or being adjacent to the electronic device DD by a certain distance. In addition, the external input may include various types such as force, pressure, temperature, and light.

The electronic device DD may include a folding area FA1 and non-folding areas NFA1 and NFA2. The electronic device DD according to an embodiment may include a first non-folding area NFA1 and a second non-folding area NFA2 disposed with the folding area FA therebetween. FIGS. 1A to 1C illustrate an embodiment of the electronic device DD including one folding area FA1, but an embodiment is not limited thereto and a plurality of folding areas may be defined in the electronic device DD.

Referring to FIG. 1B, the electronic device DD according to an embodiment may be folded around a first folding axis FX1. The first folding axis FX1 is a virtual axis extending in the first direction DR1, and the first folding axis FX1 may be parallel to a long-side direction of the electronic device DD. The first folding axis FX1 may extend along the first direction DR1 on the first display surface FS.

In an embodiment, the non-folding areas NFA1 and NFA2 may be disposed adjacent to the folding area FA1 with the folding area FA1 therebetween. For example, the first non-folding area NFA1 may be disposed on one side of the folding area FA1 along the second direction DR2, and the second non-folding area NFA2 may be disposed on the other side of the folding area FA1 along the second direction DR2.

The electronic device DD may be folded around the first folding axis FX1 to be changed into an in-folded state in which one area, which overlaps the first non-folding area NFA1, of the first display surface FS and the other area, which overlaps the second non-folding area NFA2, of the first display surface FS face each other. In a state in which the electronic device DD according to an embodiment is in-folded, the second display surface RS may be visible to a user. The second display surface RS may further include an electronic module area on which an electronic module including various components is disposed, and is not limited to any one embodiment.

Referring to FIG. 1C, the electronic device DD according to an embodiment may be folded around the first folding axis FX1 to be changed into an out-folded state in which one area, which overlaps the first non-folding area NFA1, of the second display surface RS and the other area, which overlaps the second non-folding area NFA2, of the second display surface RS face each other. However, an embodiment is not limited thereto. The electronic device DD may be folded around a plurality of folding axes and thus folded so that respective one portions of the first display surface FS and the second display surface RS face each other, and the number of the folding axes and the number of the resulting non-folding areas are not particularly limited.

The electronic device DD may further include various electronic modules. For example, the electronic modules may include at least one of a camera, a speaker, a light detecting sensor, or a heat detecting sensor. The electronic modules detect an external subject received through the first or second display surface FS or RS, or provide a sound signal such as voice, to the outside through the first or second display surface FS or RS. The electronic module may include a plurality of components and is not limited to any one embodiment.

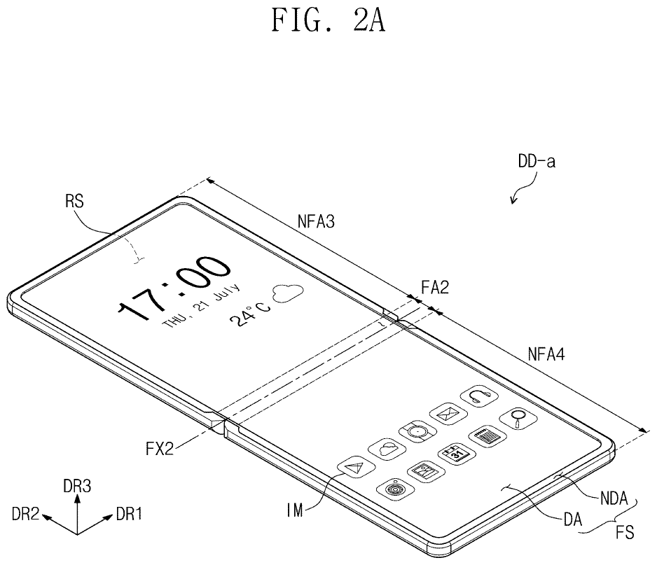

FIG. 2A is an assembled perspective view illustrating an unfolded state of an electronic device DD-a according to an embodiment of the invention. FIG. 2B is an assembled perspective view illustrating an in-folded state of the electronic device DD-a according to an embodiment of the invention.

The electronic device DD-a according to an embodiment may be folded around a second folding axis FX2 extending in one direction parallel to the first direction DR1. FIG. 2B illustrates a case in which an extending direction of the second folding axis FX2 is parallel to an extending direction of a short side of the electronic device DD-a. However, an embodiment is not limited thereto.

The electronic device DD-a according to an embodiment may include at least one folding area FA2 and non-folding areas NFA3 and NFA4, each of which is adjacent to the folding area FA2. The non-folding areas NFA3 and NFA4 may be arranged to be spaced apart from each other with the folding area FA2 therebetween.

In an embodiment, a third non-folding area NFA3 and a fourth non-folding area NFA4 may face each other, and the electronic device DD-a may be in-folded so that a display surface FS is not exposed to the outside. Alternatively, in an embodiment unlike the illustrated embodiment, the electronic device DD-a may be out-folded so that the display surface FS is exposed to the outside. In addition, the electronic device DD-a according to an embodiment may include a first display surface FS and a second display surface RS, and the first display surface FS may include a display area DA and a non-display area NDA. In addition, the electronic device DD-a may further include various electronic modules.

The electronic devices DD and DD-a according to an embodiment described with reference to FIGS. 1A to 1C, 2A, and 2B may be provided to repeat an operation from an unfolding operation to an in-folding or out-folding operation, or vice versa, but an embodiment is not limited thereto. In an embodiment, the electronic devices DD and DD-a may be provided so as to select one from the unfolding operation, the in-folding operation, and the out-folding operation. Although not illustrated, the electronic device according to an embodiment may be a flexible electronic device which includes a plurality of folding areas, or in which at least a partial area is bendable or rollable.

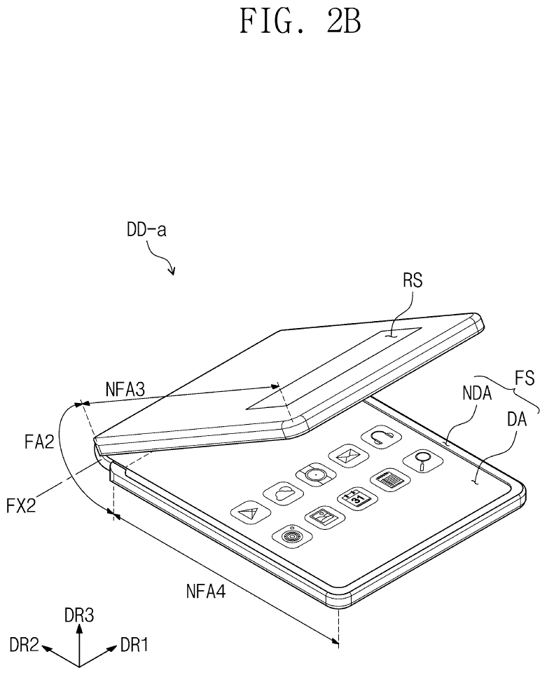

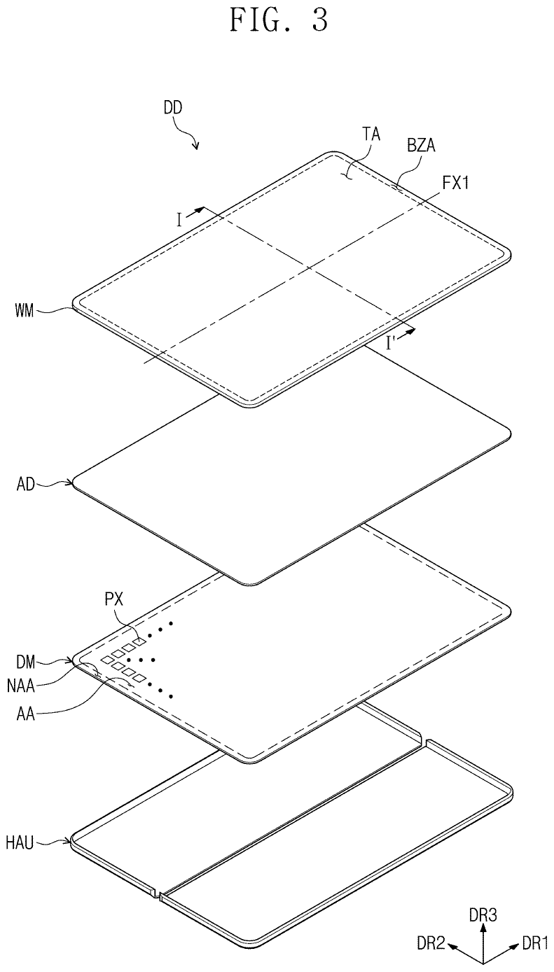

FIG. 3 is an exploded perspective view of an electronic device DD according to an embodiment of the invention. As an example, FIG. 3 illustrates an exploded perspective view of the electronic device DD according to an embodiment illustrated in FIG. 1A.

Referring to FIG. 3, the electronic device DD according to an embodiment may include a display module DM, an adhesive layer AD disposed on the display module DM, and a window WM disposed on the adhesive layer AD. The window WM may be disposed on at least one of an upper side or a lower side of the display module DM. FIG. 3 illustrates the window WM which is disposed on the upper side of the display module DM.

In addition, the electronic device DD according to an embodiment may further include an electronic module (not illustrated) disposed below the display module DM. For example, the electronic module (not illustrated) may include a camera module.

In the electronic device DD according to an embodiment, the adhesive layer AD disposed between the window WM and the display module DM may be an optically clear adhesive film (OCA) or an optically clear adhesive resin layer (OCR). The adhesive layer AD may be omitted in an embodiment.

In addition, although not illustrated, the electronic device DD according to an embodiment may further include a polarizing film disposed between the display module DM and the adhesive layer AD. The polarizing film may be a film having an optical function to improve photo-extraction efficiency of the display module DM.

In addition, although not illustrated, the electronic device DD according to an embodiment may further include a lower functional layer disposed below the display module DM. The lower functional layer may be a layer for supporting the display module DM or preventing deformation of the display module DM caused by an external impact or force. The lower functional layer may include at least one of a cushion layer, a support plate, a shielding layer, a filling layer, or an adhesive interlayer.

The electronic device DD according to an embodiment may further include a housing HAU which accommodates the display module DM, the lower functional layer, and the like. The housing HAU may be coupled to the window WM to constitute an outer appearance of the electronic device DD. The housing HAU may include a material having relatively high rigidity. For example, the housing HAU may include a plurality of frames and/or plates, each of which includes glass, plastic, or metal. The display module DM may be accommodated in an accommodation space and be protected from an external impact. Although not illustrated, the housing HAU may further include a hinge structure for easy folding or bending.

The display module DM according to an embodiment may display an image IM in response to an electrical signal and transmit/receive information of an external input. The display module DM may include a display panel and a sensor layer disposed on the display panel.

The display module DM may include an active area AA and a peripheral area NAA. The active area AA may be an area which provides the image IM (see FIG. 1A). A pixel PX may be disposed in the active area AA. The peripheral area NAA may be adjacent to the active area AA. The peripheral area NAA may surround the active area AA. A driving circuit, a driving line, or the like for driving the active area AA may be disposed in the peripheral area NAA.

The display module DM may include a plurality of pixels PX. Each of the pixels PX may display light in response to an electrical signal. The light displayed by the pixels PX may produce the image IM. Each of the pixels PX may include a display element. For example, the display element may be an organic light emitting element, an inorganic light emitting element, an organic-inorganic light emitting element, a micro LED, a nano LED, a quantum dot light emitting element, an electrophoretic element, an electro wetting element, or the like.

The window WM may cover the entirety of a top surface of the display module DM. The window WM may have a shape corresponding to a shape of the display module DM. The window WM may have flexibility with which a shape thereof is changed as the electronic device DD changes into a folded or bent shape. The window WM may function to protect the display module DM from an external impact.

The window WM may include a transmission area TA and a bezel area BZA. The transmission area TA may overlap at least a portion of the active area DM of the display module DM. The transmission area TA may be an optically transparent area. For example, the transmission area TA may have a transmittance of about 90% or greater with respect to a wavelength in a visible light range. The image IM (see FIG. 1A) may be provided for a user through the transmission area TA, and the user may receive information through the image IM (see FIG. 1A).

The bezel area BZA may be an area having a relatively lower light transmittance than the transmission area TA. The bezel area BZA may define a shape of the transmission area TA. The bezel area BZA may have a certain color. The bezel area BZA may cover the peripheral area NAA of the display module DM and prevent the peripheral area NAA from being visible from the outside. However, this is illustrative, and the bezel area BZA may be omitted in the window WM according to an embodiment.

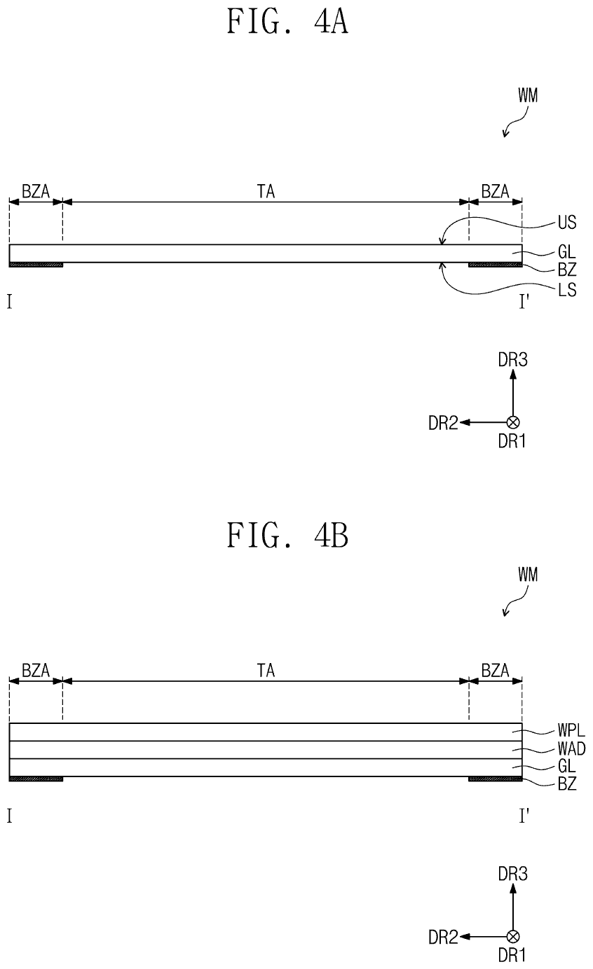

FIGS. 4A and 4B are each a cross-sectional view of a window WM according to an embodiment of the invention. FIGS. 4A and 4B are each a cross-sectional view corresponding to line I-I′ in the window WM of the electronic device DD according to an embodiment of the invention in FIG. 3.

Referring to FIGS. 4A and 4B, the window WM according to an embodiment includes a glass substrate GL. A material included by the glass substrate GL according to an embodiment will be described later in detail.

The glass substrate GL according to an embodiment may include a top surface US and a bottom surface LS. The top surface US and the bottom surface LS of the glass substrate GL may oppose each other in the third direction DR3, and a normal direction to each of the top surface US and the bottom surface LS may be parallel to the third direction DR3. The top surface US of the glass substrate GL may be exposed to the outside of the electronic device DD.

The window WM may further include a print layer BZ disposed on the bottom surface LS of the glass substrate GL. The print layer BZ may be formed on the bottom surface LS of the glass substrate GL through a printing or deposition process, and the print layer BZ may be directly disposed on the bottom surface LS of the glass substrate GL.

The print layer BZ may be disposed on at least a portion of the bottom surface LS of the glass substrate GL and define a bezel area BZA. The print layer BZ may be a portion corresponding to the peripheral area NAA (see FIG. 3) of the display module DM (see FIG. 3).

The print layer BZ may have a relatively lower light transmittance than the glass substrate GL. For example, the print layer BZ may have a certain color. Accordingly, the print layer BZ may selectively transmit or reflect only light of a specific color. Alternatively, the print layer BZ may be a light blocking layer which absorbs incident light. The light transmittance and the color of the print layer BZ to be provided may vary according to the type of the electronic device DD and the shape of the electronic device DD.

Referring to FIG. 4B, the window WM according to an embodiment may further a window protective layer WPL disposed on the glass substrate GL. The window protective layer WPL may be disposed on an upper side of the glass substrate GL and become the uppermost layer of each of the electronic devices DD and DD-a (see FIGS. 1A and 2A). The window protective layer WPL may be a layer exposed to the outermost surface of each of the electronic devices DD and DD-a (see FIGS. 1A and 2A) and function to protect the glass substrate GL, the display module DM, and the like.

The window protective layer WPL may have a thickness of about 30 μm to about 100 μm. In the case of the thickness in the foregoing range, the window protective layer WPL may have durability and also maintain flexibility to enable folding or the like. The window protective layer WPL may have a single-layer structure or a multilayer structure. For example, the window protective layer WPL may have a single-layer structure as illustrated in FIG. 4B, or may have a two-layer structure in which two layers are stacked.

The window WM according to an embodiment may further include a window adhesive layer WAD disposed between the glass substrate GL and the window protective layer WPL. The window adhesive layer WAD may bond the glass substrate GL to the window protective layer WPL. The window adhesive layer WAD may be an optically clear adhesive film (OCA) or an optically clear adhesive resin layer (OCR).

In addition, the window WM according to an embodiment may further include a window functional layer (not illustrated) including at least one of a hard coating layer or an anti-fingerprint layer. The window functional layer (not illustrated) may be a hard coating layer, an anti-fingerprint layer, or a layer which simultaneously performs functions of the hard coating layer and the anti-fingerprint layer. The hard coating layer may be a layer for imparting physical strength to the window WM. The anti-fingerprint layer may be a layer which prevents external contamination such as fingerprints, and suppresses abrasion caused by external friction. In addition, the window functional layer (not illustrated) may further have an anti-reflective or anti-glare function.

The glass substrate GL according to an embodiment of the invention is an ultra-thin glass substrate having a thickness of about 100 μm or less. In an embodiment, a thickness of the glass substrate GL may be about 50 μm to about 100 μm. As the glass substrate GL has the thickness in the foregoing range, the glass substrate GL may be bendable or foldable and also have appropriate impact resistance characteristics so as to be used for a flexible electronic device.

Thus, the glass substrate GL according to an embodiment of the invention may include suitable amounts of a Group IIIA element oxide such as B₂O₃ or Al₂O₃, an alkali metal oxide such as Li₂O, Na₂O, or K₂O, and SiO₂, and thus have a thickness of a predetermined value or greater and also have a low Young's modulus, thereby providing a window applicable to a foldable electronic device. In addition, as the glass substrate GL according to an embodiment has appropriate levels of hardness and thickness, the glass substrate GL may have excellent impact resistance characteristics and also have improved surface quality characteristics, thereby improving display quality of the electronic device.

The glass substrate GL according to an embodiment may include the alkali metal oxide such as Li₂O, Na₂O, or K₂O, the Group IIIA element oxide such as B₂O₃ or Al₂O₃, and SiO₂.

SiO₂ is a main component of glass and may serve as a network former. The alkali metal oxide such as Li₂O, Na₂O, or K₂O may serve as a network modifier. B₂O₃ may be provided as a network former like SiO₂, and reduce a coefficient of thermal expansion of glass and strengthen a network structure. Al₂O₃ may serve to increase mechanical strength and chemical durability of the glass substrate GL and prevent crystallization.

The glass substrate GL may include SiO₂ and B₂O₃, thereby reducing a coefficient of thermal expansion of the glass substrate GL and increasing the mechanical strength thereof. The glass substrate GL may include the alkali metal oxide such as Li₂O, Na₂O, or K₂O, thereby decreasing a glass transition temperature of the glass substrate GL to decrease a viscosity. The glass substrate GL may include Al₂O₃, thereby providing the glass substrate GL having high mechanical strength. Here, the glass transition temperature may be a temperature at which an amorphous material changes from a hard, glassy, and rigid state to a more flexible, rubbery state, or vice versa.

The glass substrate GL may not include an alkali earth metal oxide such as MgO, CaO, and BaO. The glass substrate GL may not include a metal oxide having an oxidation number of +2, for example, PbO and ZnO. In the glass substrate GL, a strengthening process for introducing the alkali earth metal oxide, for example, MgO, CaO, and BaO, and the metal oxide having an oxidation number of +2, for example, PbO and ZnO, may be omitted in a manufacture process of the glass substrate GL, thereby reducing a process time and reducing consumption of energy necessary for the manufacture process. Moreover, generation of by-products may be suppressed to reduce environmental pollution caused by the manufacture process of the glass substrate GL.

The glass substrate GL may not include an alkali earth metal compound, for example, MgO, CaO, and BaO, and the metal oxide having an oxidation number of +2, for example, PbO and ZnO, and thus the hardness and chemical durability of the glass substrate GL may be reduced compared to a case in which the alkali earth metal compound is included. However, the glass substrate GL according to an embodiment may have the large thickness of about 50 μm or greater, and accordingly, when the glass substrate GL is applied to the foldable electronic device DD (see FIG. 3), the glass substrate GL may have strength sufficient to protect a lower component.

In another embodiment, the glass substrate GL may include the alkali earth metal oxide, for example, MgO, CaO, and BaO, or the metal oxide having an oxidation number of +2, for example, PbO and ZnO. The glass substrate GL may include at least one of MgO, CaO, BaO, PbO, or ZnO but in a smaller amount than other components. In an embodiment, the glass substrate GL may further include XO, and X may be at least one selected from Ca, Mg, Ba, Pb, and Zn. XO may be included in an amount of about 1 mol % or less based on an entirety of the glass substrate GL. XO may be included in an amount of about 0.1 mol % or less based on the entirety of the glass substrate GL. XO may be included in an amount of greater than 0 mol % based on an entirety of the glass substrate GL.

The glass substrate GL according to an embodiment may have the thickness of about 50 μm to about 100 μm and also include the alkali metal oxide such as Li₂O, Na₂O, or K₂O, the Group IIIA element oxide such as B₂O₃ or Al₂O₃, and SiO₂, thereby being applied to the window WM of the foldable electronic device DD (see FIG. 3) and also exhibiting the excellent impact resistance characteristics and surface quality characteristics. The glass substrate GL according to an embodiment may include the alkali metal oxide such as Li₂O, Na₂O, or K₂O, the Group IIIA element oxide such as B₂O₃ or Al₂O₃, and SiO₂.

The glass substrate GL according to an embodiment includes about 5 mol % to about 45 mol % of SiO₂, about 5 mol % to about 30 mol % of R₂O, and about 45 mol % to about 90 mol % of A₂O₃, based on the entirety of the glass substrate GL. For example, the glass substrate GL according to an embodiment may include about 5 mol % to about 20 mol % of SiO₂, about 5 mol % to about 30 mol % of R₂O, and about 55 mol % to about 90 mol % of A₂O₃, based on the entirety of the glass substrate GL. In R₂O, R may be at least one selected from K, Na, and Li, and R₂O may correspond to the foregoing alkali metal oxide. In A₂O₃, A may be at least one selected from B and Al, and A₂O₃ may correspond to the foregoing Group IIIA element oxide. The glass substrate GL may include the materials in the foregoing ranges, respectively, thereby having an appropriate hardness to improve the impact resistance characteristics and also having the low Young's modulus and improving the surface quality characteristics.

In an embodiment, the glass substrate GL may not include Al₂O₃ but include only B₂O₃. The glass substrate GL may include about 5 mol % to about 45 mol % of SiO₂, about 5 mol % to about 30 mol % of R₂O, and about 45 mol % to about 90 mol % of B₂O₃, based on the entirety of the glass substrate GL. In R₂O, R may be at least one selected from K, Na, and Li, and R₂O may correspond to the foregoing alkali metal oxide. For example, the glass substrate GL may include about 5 mol % to about 15 mol % of SiO₂, about 5 mol % to about 15 mol % of R₂O, and about 75 mol % to about 90 mol % of B₂O₃, based on the entirety of the glass substrate GL.

In another embodiment, the glass substrate GL may include both Al₂O₃ and B₂O₃. The glass substrate GL may include about 5 mol % to about 20 mol % of SiO₂, about 5 mol % to about 30 mol % of R₂O, about 55 mol % to about 70 mol % of B₂O₃, and greater than 0 mol % and equal to or less than 20 mol % of Al₂O₃, based the entirety of the glass substrate GL. In R₂O, R may be at least one selected from K, Na, and Li, and R₂O may correspond to the foregoing alkali metal oxide. For example, the glass substrate GL may include about 5 mol % to about 15 mol % of SiO₂, about 5 mol % to about 15 mol % of R₂O, about 55 mol % to about 70 mol % of B₂O₃, and greater than 0 mol % and equal to or less than 20 mol % of Al₂O₃, based on the entirety of the glass substrate GL.

In a temperature range of about −40° C. to about 200° C., the Young's modulus of the glass substrate GL according to an embodiment is about 30 GPa to about 50 GPa. In the temperature range of about −40° C. to about 200° C., the glass substrate GL according to an embodiment may have the low Young's modulus of about 30 GPa to about 50 GPa. As described above, the glass substrate GL may include the alkali metal oxide such as Li₂O, Na₂O, or K₂O, the Group IIIA element oxide such as B₂O₃ or Al₂O₃, and SiO₂ in the above-mentioned amount ranges, respectively, thereby having the low Young's modulus. Accordingly, even when the thickness of the glass substrate GL is about 50 μm or greater, the glass substrate GL may be applied to the window WM of the foldable electronic device DD (see FIG. 3).

A Vickers hardness of the glass substrate GL according to an embodiment may be greater than about 3.5 GPa and less than about 4.8 GPa. For example, the Vickers hardness of the glass substrate GL may be greater than about 4.1 GPa and less than about 4.3 GPa.

A brittleness of the glass substrate GL according to an embodiment may be greater than about 4.4 μm^{-0.5} and less than about 5.6 μm^{-0.5}. For example, the brittleness of the glass substrate GL may be greater than about 4.7 μm^{-0.5} and less than about 5.3 μm^{-0.5}, or may be greater than about 4.9 μm^{-0.5} and less than about 5.1 m^{-0.5}.

A fracture toughness of the glass substrate GL according to an embodiment may be greater than about 0.6 MPa*m^{0.5} and less than about 1.4 MPa*m^{0.5}. For example, the fracture toughness of the glass substrate GL may be greater than about 0.9 MPa*m^{0.5} and less than about 1.1 MPa*m^{0.5}.

A Poisson's ratio of the glass substrate GL according to an embodiment may be greater than about 0.2 and less than about 0.3. For example, the Poisson's ratio of the glass substrate GL may be greater than about 0.24 and less than about 0.26.

The glass transition temperature of the glass substrate GL according to an embodiment may be about 350° C. to about 700° C. For example, the glass transition temperature of the glass substrate GL may be about 400° C. to about 600° C. The glass substrate GL may have the relatively low glass transition temperature of about 300° C. to about 700° C., thereby reducing the consumption of the energy necessary for the manufacture process of the glass substrate GL.

A density of the glass substrate GL according to an embodiment may be about 1.9 g/cm³ to about 2.3 g/cm³. For example, the density of the glass substrate GL may be about 2.05 g/cm³ to about 2.23 g/cm³.

The density of the glass substrate GL according to an embodiment may be about 1.9 g/cm³ to about 2.3 g/cm³. For example, the density of the glass substrate GL may be about 2.05 g/cm³ to about 2.23 g/cm³.

A surface quality index of the glass substrate GL according to an embodiment may be about 0.01 Kc to about 0.1 Kc. The surface quality index (Kc) is an index for determining whether or not a surface of an object to be measured is smooth, and the lower the surface quality index (Kc), the smoother the surface of the object to be measured. The glass substrate GL may not undergo the strengthening process for introducing the alkali earth metal oxide, for example, MgO, CaO, and BaO, or the metal oxide having an oxidation number of +2, for example, PbO and ZnO, but have the relatively large thickness of about 50 μm to about 100 μm, thereby having the low surface quality index of about 0.01 Kc to about 0.1 Kc. Accordingly, a curl phenomenon may be prevented from being generated in the glass substrate GL and the window WM including the glass substrate GL. When the glass substrate GL is applied to the window WM and assembled to the electronic device DD (see FIG. 3), a surface quality index of the first display surface FS (see FIG. 1A) of the electronic device DD (see FIG. 3) may be about 0.1 Kc to about 0.4 Kc.

Table 1 shows a composition and a Young's modulus property of a glass substrate in each sample group. Table 1 shows Young's modulus values evaluated on the samples, each of which includes Na₂O, B₂O₃, and SiO₂ and which are different in detailed amounts. The Young's moduli were measured using elastic modulus, shear modulus, and Poisson's ratio measurements with ultrasonic echo velocity under ASTM E 494 test procedure.

TABLE 1

| Sample | Composition (mol %) | | | Young's Modulus |
|---|---|---|---|---|
| group | Na₂O | B₂O₃ | SiO₂ | (GPa) |
| #1 | 10 | 80 | 10 | 36 |
| #2 | 10 | 45 | 45 | 47.1 |
| #3 | 10 | 40 | 50 | 51.2 |
| #4 | 5 | 40 | 55 | 50.2 |
| #5 | 5 | 35 | 60 | 52.7 |

Table 2 shows a composition, a Young's modulus, and a density of a glass substrate in each sample group. Table 2 shows Young's modulus values and densities evaluated on the samples, each of which includes Na₂O, Al₂O₃, B₂O₃, and SiO₂ and which are different in detailed amounts. The Young's moduli were evaluated in the same method as stated in Table 1, and the densities were calculated by utilizing Archimedes' method in which a difference between a dry weight of a sample and a weight of the sample under water is used.

TABLE 2

| Sample | Composition (mol %) | | | | Young's Modulus | Density |
|---|---|---|---|---|---|---|
| group | Na₂O | Al₂O₃ | B₂O₃ | SiO₂ | (GPa) | (g/cm³) |
| #6 | 10 | 5 | 75 | 10 | 32.4 | 2.06 |
| #7 | 10 | 7.5 | 72.5 | 10 | 34.2 | 2.08 |
| #8 | 10 | 10 | 70 | 10 | 35.7 | 2.10 |
| #9 | 10 | 10 | 30 | 50 | 57.1 | 2.206 |
| #10 | 10 | 5 | 35 | 50 | 54.1 | 2.196 |
| #11 | 10 | 5 | 40 | 45 | 49.2 | 2.161 |
| #12 | 10 | 5 | 30 | 55 | 58.1 | 2.254 |

Referring to Tables 1 and 2, it may be confirmed that among the glass substrates, the glass substrate in the sample group which does not include an alkali earth metal oxide, for example, MgO, CaO, and BaO, or a metal oxide having an oxidation number of +2, for example, PbO and ZnO, but includes an alkali metal oxide such as Li₂O, Na₂O, or K₂O, a Group IIIA element oxide such as B₂O₃ or Al₂O₃, and SiO₂ in the above-mentioned amount ranges, has a lower Young's modulus than the glass substrate which does not satisfy the amount ranges. It is thought that a glass substrate according to an embodiment has a low Young's modulus as the glass substrate according to an embodiment does not include the alkali earth metal oxide, for example, MgO, CaO, and BaO, or the metal oxide having an oxidation number of +2, for example, PbO and ZnO, but includes the alkali metal oxide such as Li₂O, Na₂O, or K₂O, the Group IIIA element oxide such as B₂O₃ or Al₂O₃, and SiO₂ in the above-mentioned amount ranges. The glass substrate according to an embodiment may have a hardness at an equivalent level to a glass substrate according to a comparative example and have the lower Young's modulus, thereby being applied to the foldable display device and electronic device.

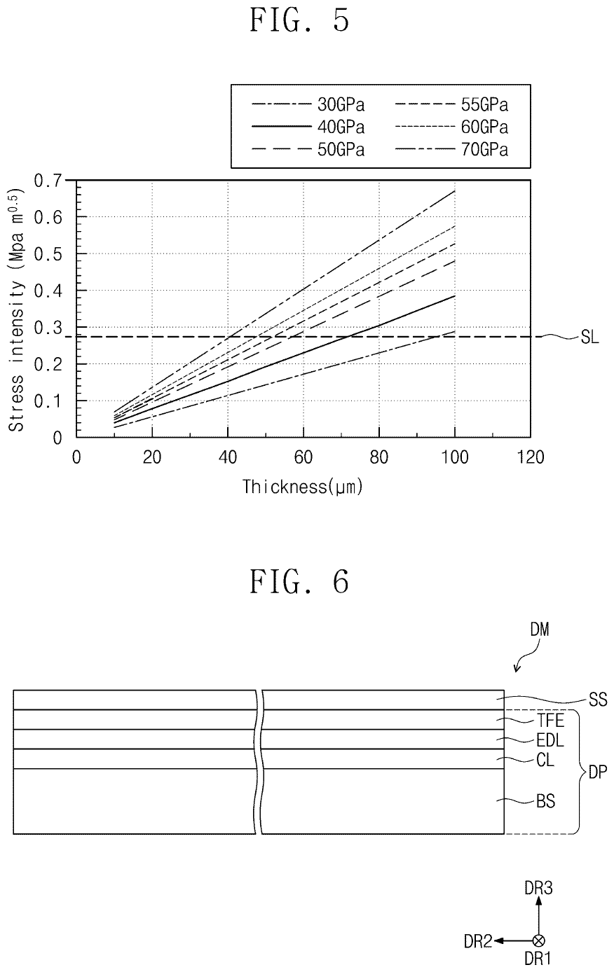

Table 3 shows compressive stress applied to a glass substrate according to a Young's modulus, a thickness, and a curvature of the glass substrate. Table 3 shows results obtained by measuring stress intensities at a moment at which a flaw size exceeds a set critical value when the glass substrate is folded with a curvature of about 1.98 R. FIG. 5 is a graph illustrating stress intensity through thickness for glass substrates having different Young's moduli. FIG. 5 shows results obtained by measuring stress intensities at a point with a depth of about 50 nm when the glass substrates are folded with the curvature of about 1.98 R.

TABLE 3

| Curvature | Thickness | 30 | 40 | 50 | 55 | 60 | 70 |
|---|---|---|---|---|---|---|---|
| (mm) | (μm) | GPa | GPa | GPa | GPa | GPa | GPa |
| R = 1.98 | 30 | 0.158 | 1.205 | 0.253 | 0.277 | 0.301 | 0.348 |
| Flaw size: 20 | 50 | 0.263 | 0.342 | 0.422 | 0.461 | 0.501 | 0.581 |
| nm | 70 | 0.368 | 0.479 | 0.591 | 0.646 | 0.702 | 0.813 |
| | 100 | 0.526 | 0.685 | 0.844 | 0.923 | 1.002 | 1.161 |
| R = 1.98 | 30 | 0.241 | 0.316 | 0.391 | 0.429 | 0.467 | 0.542 |
| Flaw size: 50 | 50 | 0.401 | 0.527 | 0.652 | 0.715 | 0.778 | 0.903 |
| nm | 70 | 0.562 | 0.738 | 0.913 | 1.001 | 1.089 | 1.265 |
| | 100 | 0.803 | 1.054 | 1.305 | 1.430 | 1.556 | 1.807 |
| R = 1.98 | 30 | 0.334 | 0.441 | 0.547 | 0.601 | 0.654 | 0.760 |
| Flaw size: 100 | 50 | 0.557 | 0.735 | 0.912 | 1.001 | 1.090 | 1.267 |
| nm | 70 | 0.780 | 1.029 | 1.277 | 1.401 | 1.526 | 1.774 |
| | 100 | 1.115 | 1.470 | 1.825 | 2.002 | 2.180 | 2.534 |

Referring to Table 3, it may be confirmed that as the thickness of the glass substrate increases, the stress applied to the glass substrate by folding is increased in proportion to the thickness. The Young's modulus of the glass substrate and the stress applied to the glass substrate by folding are in inverse proportion to each other. Even when the glass substrate according to an embodiment has a somewhat large thickness of about 50 micrometers to about 100 micrometers as described above, the glass substrate according to an embodiment may have the lower Young's modulus to reduce the stress caused by folding, and thus may be applicable to the window of the foldable electronic device.

Referring to FIG. 5, it may be confirmed that as the thickness of the glass substrate increases, the stress intensity caused by folding is increased in proportion to the thickness. The Young's modulus of the glass substrate and the stress intensity applied to the glass substrate by folding are in inverse proportion to each other. Even when the glass substrate according to an embodiment has the somewhat large thickness of about 50 micrometers to about 100 micrometers as described above, the glass substrate according to an embodiment may have the lower Young's modulus to reduce the stress intensity caused by folding. A reference line SL illustrated in FIG. 5 may represent a critical point at which a crack does not grow. In a case in which the glass substrate has the low Young's modulus of about 30 GPa to about 50 GPa, the glass substrate may have a stress intensity below the reference line SL defined at a point at which the stress intensity is about 0.27 MPa*m^{0.5}, although the thickness of the glass substrate is about 50 μm or greater. Accordingly, fatigue characteristics of the electronic device may be improved.

FIG. 6 is a cross-sectional view of a display module DM according to an embodiment of the invention. The display module DM may include a display panel DP and a sensor layer SS disposed on the display panel DP.

The display panel DP may include a base layer BS, a circuit layer CL, a light emitting element layer EDL, and an encapsulation layer TFE.

The base layer BS may be a member which provides a base surface on which the circuit layer CL is disposed. The base layer BS may be a rigid substrate, or a flexible substrate capable of bending, folding, rolling, or the like. The base layer BS may be a glass substrate, a metal substrate, a polymer substrate, or the like. However, an embodiment of the invention is not limited thereto, and the base layer BS may be an inorganic layer, an organic layer, or a composite material layer.

The circuit layer CL may be disposed on the base layer BS. The circuit layer CL may include an insulating layer, a semiconductor pattern, a conductive pattern, a signal line, and the like. The insulating layer, a semiconductor layer, and a conductive layer may be formed on the base layer BS through coating, deposition or the like, and then, the insulating layer, the semiconductor layer, and the conductive layer may be selectively patterned by performing a photolithography process and an etching process multiple times. Thereafter, the semiconductor pattern, the conductive pattern, and the signal line, which are included in the circuit layer CL, may be formed.

The light emitting element layer EDL may be disposed on the circuit layer CL. The light emitting element layer EDL may include a light emitting element. For example, the light emitting element may include an organic light emitting material, an inorganic light emitting material, an organic-inorganic light emitting material, a quantum dot, a quantum rod, a micro LED, or a nano LED.

The encapsulation layer TFE may be disposed on the light emitting element layer EDL. The encapsulation layer TFE may cover the light emitting element layer EDL. The encapsulation layer TFE may protect the light emitting element layer EDL from moisture, oxygen, and foreign matter such as dust particles.

The sensor layer SS may be disposed on the display panel DP. The sensor layer SS may detect an external input applied from the outside. The external input may be a user's input. The user's input may include various types of external inputs such as part of the user's body, light, heat, pen, or pressure.

The sensor layer SS may be formed on the display panel DP through a continuous process. In this case, the sensor layer SS may be directly disposed on the display panel DP. Here, “being directly disposed” may mean that a third component is not disposed between the sensor layer SS and the display panel DP. That is, a separate adhesive member may not be disposed between the sensor layer SS and the display panel DP. For example, the sensor layer SS may be directly disposed on the encapsulation layer TFE of the display panel DP. The sensor layer SS may be coupled to the display panel DP through an adhesive member. The adhesive member may include a general adhesive or adhesive agent.

An optical layer (not illustrated) may be further disposed on the sensor layer SS. The optical layer may be directly disposed on the sensor layer SS. The optical layer may be formed on the sensor layer SS through a continuous process. The optical layer may reduce reflection of external light incident from the outside of the display module DM. The optical layer may include a polarizing layer or a color filter layer.

In an embodiment, the sensor layer SS may be omitted, and the optical layer may be directly disposed on the display panel DP. In an embodiment, positions of the sensor layer SS and the optical layer may be exchanged.

The window according to the embodiment may include the glass substrate including the suitable amounts of the Group IIIA element oxide such as B₂O₃ or Al₂O₃, the alkali metal oxide such as Li₂O, Na₂O, or K₂O, and SiO₂, and having the thickness of the predetermined value or greater and also having the low Young's modulus. Accordingly, the window may be applicable to the foldable electronic device and also have the excellent impact resistance characteristics and surface quality characteristics.

The display device and the electronic device according to the embodiment may each include the window including the glass substrate having the excellent impact resistance characteristics and surface quality characteristics, thereby having the improved impact resistance characteristics and exhibiting the improved display quality.

In the above, description has been made with reference to embodiments of the invention, but those skilled or of ordinary skill in the art may understand that various modifications and changes may be made to the invention insofar as such modifications and changes do not depart from the spirit and technical scope of the invention set forth in the claims to be described later. Therefore, the technical scope of the invention is not to be limited to the contents stated in the detailed description of the specification, but should be determined by the claims.

What is claimed is:

1. A window comprising:
a glass substrate having a thickness of about 50 micrometers (μm) to about 100 μm,
wherein the glass substrate comprises about 5 mole percents (mol %) to about 45 mol % of SiO₂, about 5 mol % to about 30 mol % of R₂O, and about 45 mol % to about 90 mol % of A₂O₃, based on an entirety of the glass substrate,
wherein R is at least one selected from potassium (K), sodium (Na), and lithium (Li), and
A is at least one selected from boron (B) and aluminum (Al),
wherein, in a temperature range of about −40° C. to about 200° C., a Young's modulus of the glass substrate is about 30 gigapascals (GPa) to about 50 GPa.

2. The window of claim 1, wherein the glass substrate does not comprise CaO, MgO, BaO, PbO, and ZnO.

3. The window of claim 1, wherein the glass substrate is composed of SiO₂, R₂O, and A₂O₃.

4. The window of claim 1, wherein the glass substrate further comprises XO, and X is at least one selected from Ca, Mg, Ba, Pb, and Zn,
wherein the glass substrate comprises greater than 0 mol % and equal to or less than 1 mol % of XO based on of the entirety of the glass substrate.

5. The window of claim 1, wherein the glass substrate comprises Na₂O or K₂O but does not comprise Li₂O.

6. The window of claim 1, wherein a glass transition temperature of the glass substrate is about 350° C. to about 700° C.

7. The window of claim 1, wherein a density of the glass substrate is about 1.9 grams per cubic centimeters (g/cm³) to about 2.3 g/cm³.

8. The window of claim 1, wherein a surface quality index of the glass substrate is about 0.01 Kc to about 0.1 Kc.

9. The window of claim 1, wherein the glass substrate comprises about 45 mol % to about 90 mol % of B₂O₃.

10. The window of claim 1, wherein the glass substrate comprises about 55 mol % to about 70 mol % of B₂O₃ and comprises greater than 0 mol % and equal to or less than 20 mol % of Al₂O₃.

11. A display device comprising:
a display module; and
a window disposed on the display module and comprising a glass substrate having a thickness of about 50 μm to about 100 μm,
wherein the glass substrate comprises about 5 mol % to about 45 mol % of SiO₂, about 5 mol % to about 30 mol % of R₂O, and about 45 mol % to about 90 mol % of A₂O₃, based on an entirety of the glass substrate,
wherein R is at least one selected from K, Na, and Li, and
A is at least one selected from B and Al.

12. The display device of claim 11, wherein, in a temperature range of about −40° C. to about 200° C., a Young's modulus of the glass substrate is about 30 GPa to about 50 GPa.

13. The display device of claim 11, wherein a glass transition temperature of the glass substrate is about 350° C. to about 700° C.

14. The display device of claim 11, wherein a density of the glass substrate is about 1.9 g/cm³ to about 2.3 g/cm³.

15. The display device of claim 11, wherein a surface quality index of the glass substrate is about 0.01 Kc to about 0.1 Kc.

16. An electronic device comprising:
a display module; and
a window disposed on the display module and comprising a glass substrate having a thickness of about 50 μm to about 100 μm,
wherein the glass substrate comprises about 5 mol % to about 45 mol % of SiO₂, about 5 mol % to about 30 mol % of R₂O, and about 45 mol % to about 90 mol % of A₂O₃, based on an entirety of the glass substrate,
wherein R is at least one selected from K, Na, and Li, and
A is at least one selected from B and Al,
wherein, in a temperature range of about −40° C. to about 200° C., a Young's modulus of the glass substrate is about 30 GPa to about 50 GPa.

17. The electronic device of claim 16, further comprising an adhesive layer disposed between the display module and the window.

18. The electronic device of claim 16, wherein the electronic device comprises a folding area, and a first non-folding area and a second non-folding area disposed with the folding area therebetween,
wherein the folding area is folded around a folding axis.

19. The electronic device of claim 16, wherein the glass substrate does not comprise CaO, MgO, BaO, PbO, and ZnO.

20. The electronic device of claim 16, wherein a surface quality index of the glass substrate is about 0.01 Kc to about 0.1 Kc.
